(19) United States
(12) Patent Application Publication
(10) Pub. No.: US 2024/0419081 A1
(43) Pub. Date: Dec. 19, 2024

(54) METHOD TO REDUCE DEFECTS POST-SEQUENTIAL INFILTRATION SYNTHESIS

(71) Applicant: Applied Materials, Inc., Santa Clara, CA (US)

(72) Inventors: Lin ZHOU, Santa Clara, CA (US); Gabriela ALVA, Santa Clara, CA (US); Zhiyu HUANG, Santa Clara, CA (US); Yung-chen LIN, Los Angeles, CA (US); Chi-I LANG, Cupertino, CA (US)

(21) Appl. No.: 18/738,731

(22) Filed: Jun. 10, 2024

Related U.S. Application Data
(60) Provisional application No. 63/472,790, filed on Jun. 13, 2023.

(51) Int. Cl. G03F 7/38; G03F 7/004; G03F 7/20

(52) U.S. Cl. CPC G03F 7/38; G03F 7/0043; G03F 7/2043

(57) ABSTRACT

Embodiments discloses herein describe methods for treating a substrate. In one example, a method of treating a layer of a film stack includes pre-treating a surface of an underlayer of a film stack formed on a substrate and forming a metal oxide in a photoresist layer of the film stack by heating a methyl-containing material in a processing environment proximate a film stack. The film stack includes the photoresist layer disposed on top of and in contact with an underlayer, and the underlayer disposed on top of a substrate. The metal oxide implanted photoresist later is then etched.

### CROSS-REFERENCE TO RELATED APPLICATIONS

This application claims benefit to U.S. Provisional Patent Application No. 63/472,790, filed Jun. 13, 2023, the entirety of which is herein incorporated by reference.

### BACKGROUND

### Field

Examples of the present disclosure generally relate to methods for enhancing photoresist profile control. Particularly, examples of the present disclosure provide methods for forming metal-oxides in the photoresist to improve profile control while reducing defects in post-sequential infiltration synthesis (SIS) processes.

### Description of the Related Art

Integrated circuits have evolved into complex devices that can include millions of components (e.g., transistors, capacitors and resistors) on a single chip. Photolithography may be used to form components on a chip. Generally the process of photolithography involves forming a photoresist layer on a substrate. The photoresist layer may be formed by, for example, spin-coating. The photoresist layer may include a resist resin and a photoacid generator. The photoacid generator, upon exposure to electromagnetic radiation in the subsequent exposure stage, alters the solubility of the photoresist in the development process. The electromagnetic radiation may have any suitable wavelength, such as a wavelength in the extreme ultra violet region, and can be from any suitable source, e.g., a 193 nm ArF laser, an electron beam, an ion beam, or other source. Excess solvent may then be removed in a pre-exposure bake process.

During an exposure stage, a photomask or reticle may be used to selectively expose certain regions of a photoresist layer disposed on the substrate to electromagnetic radiation. Other exposure methods may be maskless exposure methods. Exposure to light may decompose the photoacid generator, which generates acid and results in a latent acid image in the resist resin. After exposure, the substrate may be heated in a post-exposure bake process. During the post-exposure bake process, the acid generated by the photoacid generator reacts with the resist resin in the photoresist layer, changing the solubility of the resist of the photoresist layer during a subsequent development process.

After the post-exposure bake, the substrate and the photoresist layer are developed and rinsed. Subsequently, a patterned photoresist layer is then formed on the substrate. Openings are defined within the patterned photoresist layer, after the development and rinse processes, exposing the underlying target material for etching to transfer features onto a target material. Factors such as inaccurate control or low resolution of the lithography exposure process, or resilience of the patterned layer, may cause poor critical dimension of the patterned photoresist layer, resulting in unacceptable line width roughness (LWR). Large line width roughness (LWR) of the patterned photoresist layer may result in inaccurate feature transfer to the target material, which can eventually lead to premature device failure and yield loss.

One approach to improve pattern transfer includes performing a post-sequential infiltration synthesis process to infiltrate a metal oxide material into the photoresist. The metal oxide incorporation into the photoresist improves etch resistance and improves pattern transfer to underlying layers. However, the metal oxide can infiltrate to underlayer trench areas which can cause undesirable bridge defects during subsequent pattern transfer processes.

Therefore, there is a need for improved processes for patterning a photoresist layer.

### SUMMARY

In one example, a method of treating a layer of a film stack includes pre-treating a surface of an underlayer of a film stack formed on a substrate and forming a metal oxide in a photoresist layer of the film stack by heating a methyl-containing material in a processing environment proximate a film stack. The film stack includes the photoresist layer disposed on top of and in contact with an underlayer, and the underlayer disposed on top of a substrate. The metal oxide implanted photoresist later is then etched.

In another example, a method treating a layer of a film stack is provided. The method includes forming a metal oxide in a photoresist layer of the film stack by heating a methyl-containing material in a processing environment proximate a film stack, the film stack including the photoresist layer disposed on top of and in contact with an underlayer, and the underlayer disposed on top of a substrate. A pre-treatment process is performed on a surface of the underlayer to remove the metal oxide from the underlayer and the film stack and the photoresist layer comprising the metal oxide are etched.

In yet another example, a substrate processing method if provided. The method includes disposing a substrate comprising an underlayer and a photoresist layer in a process chamber, performing a pre-treatment process on a surface of the underlayer to form a SAM material on the surface of the underlayer, exposing the photoresist material to a methyl-containing material, purging the process chamber of the methyl-containing material, oxidizing the methyl-containing material to form a treated photoresist, performing a post-treatment process on the surface of the underlayer to remove a metal oxide material from the surface of the underlayer, and etching the photoresist layer and the underlayer.

### BRIEF DESCRIPTION OF THE DRAWINGS

So that the manner in which the above recited features of examples of the present disclosure can be understood in detail, a more particular description of the disclosure, briefly summarized above, may be had by reference to examples, some of which are illustrated in the appended drawings. It is to be noted, however, that the appended drawings illustrate only typical examples of this disclosure and are therefore not to be considered limiting of its scope, for the disclosure may admit to other equally effective examples.

FIG. 1 depicts an exemplary processing chamber configured to perform a patterning and etching of a substrate according to one embodiment described herein.

FIG. 2 illustrates a flowchart of a method of patterning a film stack disposed on a substrate according to one embodiment described herein.

FIG. 3 illustrates a flowchart of a method of patterning a film stack disposed on a substrate according to one embodiment described herein.

To facilitate understanding, identical reference numerals have been used, where possible, to designate identical elements that are common to the figures. It is contemplated that elements disclosed in one example may be beneficially utilized on other examples without specific recitation.

### DETAILED DESCRIPTION

Examples of the present disclosure relate to methods for patterning photoresists. The methods disclosed herein are directed to pre-treatment and post-treatment processes utilized in photoresist patterning processes which include a sequential infiltration synthesis (SIS) process.

In a conventional resist layer, a material of the resist is selected from a polymer in order to control parameters, such as selectivity and line width roughness, when a film stack, in which the resist layer is formed, is exposed to an etchant, and vias or trenches are formed in an underlayer of the film stack. However, when the resist layer is selected from a polymer, and the underlayer is formed from complex metallic or amorphous compounds, undercuts can form at the interface of the resist layer and the underlayer. Conventional approaches to improving selectivity may involve multiple depositions of the resist layer, or improvements to the structure of the polymer of each of the resist layers. The conventional approach method, however, typically utilizes changes to the composition of the photoresist depending on the size of a feature intended to be patterned.

According to the methods disclosed herein, a metal oxide is formed in a patterned photoresist layer by an SIS process. A methyl-containing material is introduced into a semiconductor processing chamber having a film stack disposed therein. The methyl-containing material can also include one of aluminum, hafnium or zirconium. The film stack, in one example, includes a substrate, an underlayer disposed on the substrate, and the patterned photoresist layer disposed on the underlayer. The film stack, and thus the patterned photoresist layer is heated, and the methyl-containing material is absorbed into the patterned photoresist layer. Subsequently, the processing environment is purged, and the film stack is exposed to an oxidizing agent, such as H₂O. The oxidizing agent is heated under pressure and may form water or water vapor on the film stack. The oxidizing agent is absorbed into the patterned photoresist layer and oxidizes the absorbed methyl-containing material.

Upon oxidation, the methyl-containing material forms a metal oxide in the patterned photoresist layer. When the methyl-containing material is a tri-methylaluminum (TMA) precursor that is introduced into the processing environment, and subsequently purged and pumped, H₂O is introduced into the processing environment in a single pre-etch process, i.e., without repeatedly introducing TMA prior to oxidizing and etching the film stack. The pre-etch process includes any one or all of the processes of the disclosed method (discussed in detail below) prior to etching of the film stack. Beneficially, a single pre-etch process enables the metal oxide to infiltrate into the photoresist layer between about 20 nm and about 40 nm. Furthermore, the metal oxide is cross-linked throughout the entire thickness of patterned photoresist. Repeating one or all of the pre-etch processes, prior to etching the film stack, halts the infiltration of the methyl-containing material, and thus halts the infiltration of the metal oxide throughout the thickness of the photoresist layer. In some examples disclosed herein, the entire method, i.e., a full cycle that includes the pre-etch process and etching of the film stack, can then be repeated.

The methods described herein also utilize a pre-treatment, post-treatment, or combination of pre-and post-treatment operations to improve the patterning processes which incorporate SIS operations. In one embodiment, a pre-treatment process is performed on a photoresist layer prior to performing an SIS operation. In another embodiment, a post-treatment process is performed on a photoresist layer after performing an SIS operation. In another embodiment, the pre-treatment process is performed on a photoresist layer prior to performing an SIS operation and a post-treatment process is performed on the photoresist layer after performing the SIS operation. The pre-treatment process described herein increases selectivity between the photoresist layer and an underlying layer during SIS treatment. The post-treatment process described herein removes metal oxide, such as aluminum oxide, from the surface of the underlying layer after the SIS treatment has been performed.

The methods disclosed herein are independent of feature size. Advantageously, infiltration of the metal oxide into the underlayer results in a change in critical dimension of less than 1 nm, and the line width roughness is changed by less than 0.4 nm. In addition, the pre-and post-treatment methods reduce the probability of infiltration of the metal oxide into the underlayer by controlling the properties of the underlayer.

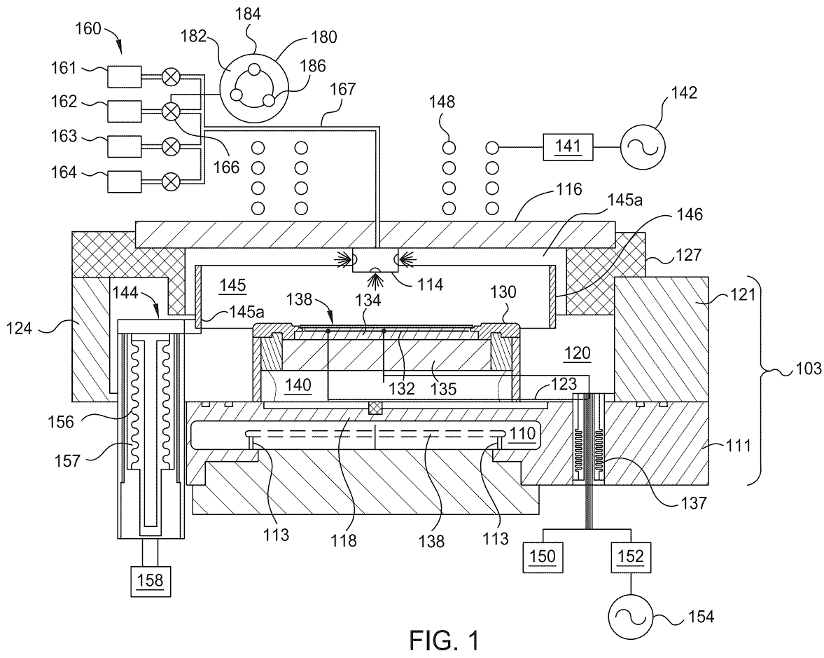

FIG. 1 is a schematic sectional view of a processing chamber 100, such as dual load lock chamber. It is understood that the processing chamber 100 is exemplary, and that other processing chambers can be adapted to perform the method disclosed herein.

In addition, the processing chamber 100 is suitable for performing a deposition process. One example of the processing chamber that may be adapted to benefit from the disclosure is a CENTRIS® Sym3™ etching processing chamber, available from Applied Materials, Inc., located in Santa Clara, California. The processing chamber can also be configured for deposition, particularly atomic layer deposition (ALD). One example of an ALD tool is an iSprint™ ALD/CVD SSW chamber configured with the Centura®, or Endura® systems.

The processing chamber 100 includes an upper chamber volume 120 for transferring and processing a substrate 138, and a lower chamber volume 110 for transferring a substrate 138. The upper chamber volume 120 and the lower chamber volume 110 are vertically stacked and are isolated from one another. Each of the lower and upper chamber volumes 110, 120 may be selectively connectable to two adjacent external environments (i.e., a factory interface and transfer chamber, both not shown) through two openings configured for substrate transferring. Examples of substrate sizes include 200 mm diameter, 250 mm diameter, 300 mm diameter and 450 mm diameter, among others.

The processing chamber 100 includes a chamber body 103. In one example, the chamber body 103 includes an upper chamber body 121 and a lower chamber body 111 coupled together to define the lower and upper chamber volumes 120, 110. The processing chamber 100 may include a hoop assembly 144 configured to confine a confinement region in the upper chamber volume 120 as well as load and unload substrates. Although the hoop assembly 144 is described in the context of a load lock chamber having a processing volume, is it understood that the hoop assembly 144 may be utilized in any suitably adapted load lock and/or processing chamber, including those having a single processing volume, where it is desirable to have a symmetrical confinement region. The processing chamber 100 may include supporting pins 113 for supporting a substrate 138 in the lower chamber volume 110.

The upper chamber volume 120 is defined by sidewalls 124 of the upper chamber body 121, a bottom wall 123 of the upper chamber body 121, an upper wall 118 of the lower chamber body 111, and a chamber lid assembly 116. The upper chamber volume 120 is suitable for patterning a material layer, forming a material layer disposed on a substrate 138, and etching. In an example that is not shown, it is also contemplated that one or more plasma generators may be optionally utilized to sustain a plasma within the upper chamber volume 120 in lieu of, or in addition to a remote plasma source. It is contemplated that other process chambers, including those from other manufactures, may be adapted to practice examples of the disclosure.

A substrate support pedestal 140 is disposed in the upper chamber volume 120 to support the substrate 138 during processing. A cover ring 130 is disposed on the ESC 134 and along the periphery of the substrate support pedestal 140. The cover ring 130 is configured to confine etching gases to a desired portion of the exposed top surface of the substrate 138, while shielding the top surface of the substrate support pedestal 140 from the plasma environment inside the processing chamber 100. Lift pins (not shown) are selectively moved through the substrate support pedestal 140 to lift the substrate 138 above the substrate support pedestal 140 to facilitate access to the substrate 138 by a transfer robot (not shown) or other suitable transfer mechanism.

The substrate support pedestal 140 includes an electrostatic chuck (ESC) 134 for holding the substrate 138 during processing. The ESC 134 uses the electrostatic attraction to hold the substrate 138 to the substrate support pedestal 140. The ESC 134 is powered by an RF power supply 154 integrated with a match circuit 152. The ESC 134 includes an electrode 132 embedded within a dielectric body. The electrode 132 is coupled to the RF power supply 154 and provides a bias, which attracts plasma ions, formed by the process gases in the upper chamber volume 120, to the ESC 134 and substrate 138 positioned thereon. The RF power supply 154 may cycle on and off, or pulse, during processing of the substrate 138. The plasma generator may be RF driven coils positioned outside or within the upper chamber volume 120, and/or an RF driven electrode disposed in the substrate support pedestal 140.

The ESC 134 may include heaters disposed therein and connected to a power source (not shown), for heating the substrate, while a cooling base 136 supporting the ESC 134 may include conduits for circulating a heat transfer fluid to maintain a temperature of the ESC 134 and substrate 138 disposed thereon. The ESC 134 is configured to perform in the temperature range desired by the thermal budget of the device being fabricated on the substrate 138. For example, the ESC 134 may be configured to maintain the substrate 138 at a temperature of about −25 degrees Celsius to about 150 degrees Celsius, such as between about 50 degrees Celsius and about 100 degrees Celsius.

The cooling base 136 is provided to assist in controlling the temperature of the substrate 138. To mitigate process drift and time, the temperature of the substrate 138 may be maintained substantially constant by the cooling base 136. In one example, the temperature of the substrate 138 is maintained throughout subsequent cleaning processes at about 30 degrees Celsius to 120 degrees Celsius.

A power source 150 is coupled to the electrode. The power source 150 provides a chucking voltage of about 200 volts to about 2000 volts to the electrode 132. The power source 150 may also include a system controller (not shown) for controlling the operation of the electrode 132 by directing a DC current to the electrode 132 for chucking and de-chucking the substrate 138. A vertical tube 137 provides a passage for power supplies, sensors and other wiring to be used by the substrate support pedestal 140.

The hoop assembly 144 is disposed in the upper chamber volume 120 according one example of the present invention. As previously stated, the hoop assembly 144 may be used in other processing chambers and/or load lock chambers. The hoop assembly 144 has at least two functions. First, the hoop assembly 144 is vertically positionable to enable transfer of substrates between the substrate support pedestal 140 and substrate transfer devices (e.g., robot end effectors) entering the upper chamber volume 120. Second, the hoop assembly 144 is also positionable to define a cylindrical confinement region 144a around the substrate 138 and region immediately above the substrate support pedestal 140 during processing, thus, providing a symmetrical processing environment in the upper chamber volume 120 which enhances processing results. The hoop assembly 144 may also be utilized solely for establishing a symmetrical confinement region within the processing volume.

The hoop assembly 144 includes a ring-shaped hoop body 146 disposed within the upper chamber volume 120. The hoop body 146 has an inner diameter, which is greater than a diameter of the substrate support pedestal 140. The hoop body 146 is coupled to a shaft 157 that extends through the chamber body 103 to a lift actuator 158. The lift actuator 158, such as a linear actuator or motor, is operable to control the vertical elevation of the hoop body 146 within the upper chamber volume 120. In one example, a bellows assembly 156 is provided to prevent leakage between the shaft 157 and the chamber body 103.

The hoop assembly 144 also includes three or more lifting fingers (not shown) attached to the hoop body 146. The lifting fingers are configured to transfer substrates between the substrate support pedestal 140 and substrate transfer devices, such as robots, extending into the upper chamber volume 120 when the hoop assembly 144 is in an upper transfer position, as shown in FIG. 1.

The hoop assembly 144 also includes a hoop 145 attached to the hoop body 146. The hoop 145 extends vertically upwards from the hoop body 146. In one example, the hoop 145 is a cylindrical ring having a substantially cylindrical inner wall 145a. A height 145b of the inner wall 145a is much greater than the thickness of the substrate 138 so that the inner wall 145a can confine a portion of the processing volume as a cylindrical confinement region 144a around and above the substrate 138. The inner wall 145a of the hoop 145 has a diameter greater than the outer diameter of the substrate support pedestal 140. In one example, the hoop 145 has a height sufficient to simultaneously overlap the substrate support pedestal 140 during processing.

A gas panel 160 is coupled by a gas line 167 to the chamber lid assembly 116 to supply process gases into the upper chamber volume 120. The gas panel 160 may include one or more process gas sources 161, 162, 163, 164 and may additionally include inert gases, non-reactive gases, and reactive gases, if desired. In one example, the gas panel 160 is configured to deliver a metal precursor, such as aluminum, hafnium, or zirconium. In one example, the gas panel is configured to deliver tri-methylaluminum (TMA). In another example, the gas panel 160 is configured to deliver gas precursors and vapor phased precursors, such as tetrakis(ethylmethylamido) zirconium(IV) (TEMAZr), and tetrakis(ethylmethylamido)hafnium(IV) (TEMAHf). The gas panel 160 can be adapted to include one or more vapor-phase precursor sources disposed in, or coupled thereto. The vapor-phase precursor source vaporizes a liquid precursor, provided from a liquid-phase precursor ampoule in fluid communication therewith, using a thermal and, or, vacuum enhanced vaporization process. In other examples, the vapor-phase precursor source is a liquid injection vaporizer configured to provide a mixture of the vapor-phase precursor and a carrier gas to the upper chamber volume 120 of the processing chamber 100. In some examples, the vapor-phase precursor source is configured to vaporize or sublimate a solid precursor.

Additional examples of process gases that may be provided by the gas panel 160 include, but are not limited to, hydrocarbon containing gas including methane (CH₄), silicon containing gas, such as sulfur hexafluoride (SF₆), silicon chloride (SiCl₄), or organic silicon containing gas, such as bis(diethylamido) Silane (BDEAS), tris(dimethylamino)silane (TDMAS), bis(tertiary-butylamino)silane (BTBAS), carbon tetrafluoride (CF₄), hydrogen bromide (HBr), hydrocarbon containing gas, argon gas (Ar), chlorine (Cl₂), nitrogen (N₂), helium (He) and oxygen gas (O₂). Additionally, process gases may include nitrogen, chlorine, fluorine, oxygen and hydrogen containing gases such as BCl₃, C₂F₄, C₄F₈, C₄F₆, C₂F₂, C₂F₆, C₅F₈, CHF₃, CH₂F₂, CH₃F, F₂, NF₃, NH₃, CO₂, SO₂, CO, N₂, NO₂, N₂O and H₂ among others.

Valves 166 control the flow of the process gases from the sources 161, 162, 163, 164 from the gas panel 160 and are managed by a controller 180. The flow of the gases supplied to the upper chamber volume 120 from the gas panel 160 may include one of the disclosed gases or combinations of the gases.

The chamber lid assembly 116 includes a nozzle 114, which is fluidically coupled to the gas line 167. The nozzle 114 has one or more ports for introducing the process gases from the sources 161, 162, 164, 163 of the gas panel 160 into the upper chamber volume 120. After the process gases are introduced into the processing chamber 100, the gases are energized to form plasma. Alternatively, a gas or precursor is provided to the upper chamber volume and the precursor is pulsed under pressure for a predetermined time, enabling the precursor to react with a substrate surface, for example, by ALD.

An antenna 148, such as one or more inductor coils, may be provided adjacent to the processing chamber 100. An antenna power supply 142 may power the antenna 148 through a match circuit 141 to inductively couple energy, such as RF energy, to the process gas to maintain a plasma formed from the process gas in the upper chamber volume 120 of the processing chamber 100. Alternatively, or in addition to the antenna power supply 142, process electrodes below the substrate 138 and/or above the substrate 138 may be used to capacitively couple RF power to the process gases to maintain the plasma within the upper chamber volume 120. The operation of the antenna power supply 142 may be controlled by a controller, such as the controller 180, which also controls the operation of other components in the processing chamber 100.

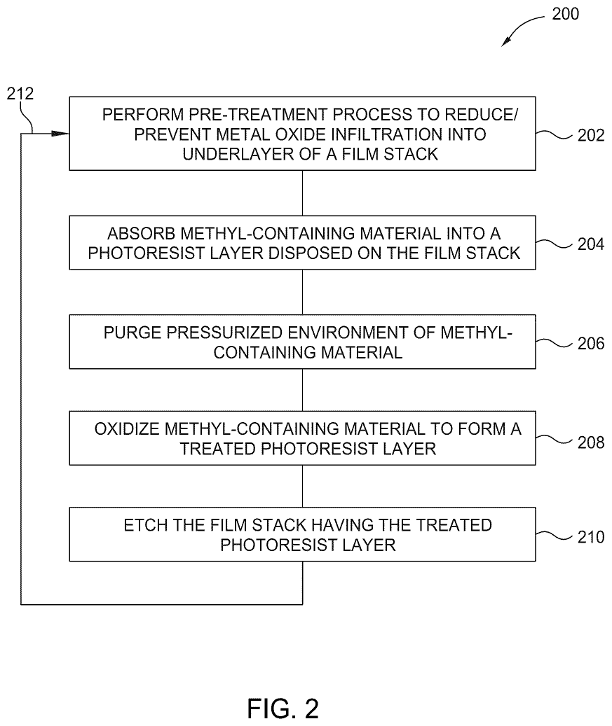

The controller 180 is coupled to the processing chamber to control the operation of the processing chamber 100. For example, the controller 180 is configured to control flow of various precursor and process gases and purge gases from gas sources, during different operations of a substrate processing sequence. The controller 180 includes a processor 182, memory 184, and support circuits 186 for the processor 182 and facilitates control of the components of the processing chamber 100. The controller 180 may be one of any form of general-purpose computer processor that can be used in an industrial setting for controlling various chambers and sub-processors. The memory 184 stores software (source or object code) that may be executed or invoked to control the operation of the processing chamber 100 in the manner described herein. The memory 184 is a non-transitory computer-readable medium and may be one or more of readily available memory such as random access memory (RAM), read only memory (ROM), or any other form of digital storage, local or remote. The memory 184 contains instructions that, when executed by the processor 182, facilitate execution of the method 200 (shown in FIG. 2).

To facilitate control of the processing chamber 100, the processor 182 may be one of any form of general purpose computer processor, or a general purpose central processing unit (CPU), each of which can be used in an industrial setting, such as a programmable logic controller (PLC), for controlling various chambers and sub-processors. Support circuits 186 are coupled to the processor 182 for supporting the processor in a conventional manner. Charged species generation, heating, and other processes are generally stored in the memory 184, typically as software routine. The software routine may also be stored and/or executed by a second CPU (not shown) that is remotely located from the processing chamber 100 being controlled by the processor 182.

The memory 184 is in the form of computer-readable storage media that contains instructions, that when executed by the processor 182, facilitates the operation of the processing chamber 100. The instructions in the memory 184 are in the form of a program product such as a program that implements the method of the present disclosure. The program code may conform to any one of a number of different programming languages. In one example, the disclosure may be implemented as a program product stored on a computer-readable storage media for use with a computer system. The program(s) of the program product define functions of the examples (including the methods described herein). Illustrative computer-readable storage media include, but are not limited to: (i) non-writable storage media (e.g., read-only memory devices within a computer such as CD-ROM disks readable by a CD-ROM drive, flash memory, ROM chips, or any type of solid-state non-volatile semiconductor memory) on which information is permanently stored; and (ii) writable storage media (e.g., floppy disks within a diskette drive or hard-disk drive or any type of solid-state random-access semiconductor memory) on which alterable information is stored. Such computer-readable storage media, when carrying computer-readable instructions that direct the functions of the methods described herein, are examples of the present disclosure.

FIG. 2 illustrates a flowchart of a method 200 of patterning a film stack. In one example, the film stack is patterned by a process of photolithography and etching. The film stack includes the substrate 138 having an underlayer disposed on top of and in contact with the substrate. The film stack also includes a photoresist layer disposed on top of and in contact with the underlayer. The photoresist layer includes one or more patterned layers. Exemplary materials for the substrate 138 include silicon, silicon oxide, doped silicon, silicon germanium, germanium, gallium arsenide, glass, sapphire, and any other materials, such as metals, metal nitrides, metal alloys, and other conductive or semi-conductive materials, depending on the application. The substrate 138, or surface thereof, can also be made of dielectric materials such as silicon dioxide, silicon nitride, organosilicates, and carbon dopes silicon oxide or nitride materials.

In one example, the underlayer may be a sol-gel solution or a nanoparticle solution. The first solution may include silicon dioxide (SiO₂) and/or silicon oxycarbide (SiOC). Proportions of SiO₂, SiOC, in the first solution are controlled to result in a first refractive index. For example, the first solution may contain a first ratio of SiO₂, or SiOC. In one embodiment, sol-gel precursors for SiO₂ may include tetramethyl orthosilicate (TMOS), methyl-tri-methoxy-silane (MTMS), and tetraethyl orthosilicate (TEOS). A first refractive layer may include a first material, and a subsequent refractive layer may include a second material different from the first material. A series of refractive layers of metals and/or dielectrics of varying dielectric constants and refractive indices, such as a graded anti-reflective coating (ARC), reduce glare, reflection, or blur. The refractive index of the encapsulation layer can be tuned from over about 2.0 to about 1.47. Exemplary ranges for a refractive index of the underlayer can be between about 1.5 and about 2.0, for example about 1.75. In yet other example, the refractive index of the underlayer 301 can between about 1.0 and about 1.5, for example about 1.47. In yet another example, the refractive index of the underlayer can be between about 1.0 and about 1.5, for example about 1.48 or about 1.49; or between about 1.0 and about 1.5, for example about 1.47.

The method 200 begins at operation 202 by performing a pre-treatment process to reduce or prevent metal oxide infiltration into the underlayer of the film stack. The pre-treatment process modifies the underlayer to minimize subsequent infiltration of metal oxide into the underlayer. In one embodiment, the pre-treatment process is performed to create a methyl-terminated surface on the underlayer by removing hydroxyl groups from the surface of the underlayer. As a result, the surface of the underlayer is changed from a hydrophilic surface to a hydrophobic surface. In one example, a self-assembled monolayer (SAM) material is formed on the underlayer. While various SAM materials may be advantageously utilized, one example of such a material formed by the deposition of hexamethyldisilazane (HMDS). In this example, HMDS is provided to the substrate by a vapor drip process utilizing a carrier gas (e.g. Ar, N, noble gases, or inert gases) at a temperature of between about 70 degrees Celsius and about 150 degrees Celsius, for example, about 100 degrees Celsius, for a time of between about 1 minute and about 20 minutes, for example, between about 5 minutes and about 10 minutes. The SAM material deposition process is performed at a pressure of between about 1 Torr and about 100 Torr, for example, about 10 Torr. The resulting SAM material increases selectivity between the photoresist and the underlayer during subsequent SIS processes by modifying the surface characteristics and reactivity of the underlayer surface to minimize or prevent infiltration into the underlayer during subsequent SIS processes. In one embodiment, the operation 202 is performed in the same process chamber as operations 204, 206, and 208. Alternatively, operation 202 is performed in a process chamber different from a chamber that performed operations 204, 206, 208.

At operation 204, a methyl-containing material is absorbed into the photoresist layer disposed on the film stack. The methyl-containing material is provided to a processing volume of a processing chamber, e.g., the upper chamber volume 120 of the processing chamber 100, having the film stack disposed therein. The methyl-containing material is provided to the processing volume (e.g., upper chamber volume 120) at a high pressure. In one example, the methyl-containing material is a gas that includes tri-methylaluminum (TMA). Alternatively, the methyl-containing material can be provided as a vapor or liquid, which can be provided to the processing volume. In one example, the vapor or liquid includes (TEMAZr) or (TEMAHf). The methyl-containing material is provided to the upper chamber volume 120 at a predetermined temperature, pressure, and time. The methyl-containing material includes aluminum atoms, hydrogen atoms, and carbon atoms. In one example, methyl-containing material is provided to the upper chamber volume 120 at the high pressure for a predetermined time and temperature. For example, the pressure can be from about 100 mTorr to about 20 Torr, such as about 1 Torr to about 10 Torr, or between about 3 Torr and about 7 Torr. The predetermined time is between about 1 second to about 45 seconds, such as between about 10 seconds and 30 seconds. In another example, the pressurized methyl-containing material is provided to the upper chamber volume 120 for about 15 seconds, or about 20 seconds, or about 30 seconds. In at least one example, the predetermined temperature is between about 0 degrees Celsius and about 150 degrees Celsius, such as about 50 degrees Celsius and about 100 degrees Celsius, such as between about 75 degrees Celsius and about 100 degrees Celsius.

The methyl-containing material is absorbed into a patterned photoresist layer by heating the upper chamber volume 120 to enable the methyl-containing material to diffuse into patterned layers of the photoresist layer. The heat also enables gaps or space to be formed between polymers which the methyl-containing material infiltrates when under pressure. Polymers within the photoresist layer are sufficiently dispersed to enable the methyl-containing material to diffuse through a top surface of the photoresist layer, enabling the methyl-containing material to occupy space between polymers. The photoresist layer is saturated with the methyl-containing material. Accordingly, the methyl-containing material is confined between the top surface and a bottom surface of the photoresist layer. Otherwise stated, the methyl-containing material is absorbed and evenly dispersed throughout a thickness of the photoresist layer, the thickness defined as a distance between the top surface and a bottom surface of the photoresist layer.

The processing volume is purged of excess or unbonded methyl-containing material at operation 206. For example, a purge gas is introduced into the upper chamber volume 120 for about 20 seconds. After about 20 seconds, the flow of the purge gas is stopped and the purge gas, along with any excess or unbonded residual methyl-containing material, is evacuated from the upper chamber volume 120 using one or more dedicated vacuum pumps for about 20 seconds. The one or more dedicated vacuum pumps (not shown) are part of a vacuum pump system (not shown), in one example. The purge gas is a non-reactive gas, which can be N₂ in one example. In another example, the purge gas is a chemically inert gas, such as Ar or He. Purging enables a top surface of the photoresist layer to be substantially free of the methyl-containing material in preparation for oxidation.

In operation 208, the methyl-containing layer is oxidized to form a treated photoresist layer. An oxidizing agent, containing oxygen atoms and hydrogen atoms, is introduced into the upper chamber volume 120. In one example, the oxidizing agent is water, which can be provided to the upper chamber volume 120 as a liquid or gas. When the methyl-containing material interacts with the oxidizing agent in an oxidation process, a metal oxide and a by-product gas are formed within the photoresist layer. The by-product gas diffuses out of the photoresist layer passing through the surfaces of the pattered layers, including the top surface. There is substantially no diffusion of the by-product gas through the underlayer, since the top surface of the photoresist layer is in contact with the upper chamber volume 120, and a material included in the underlayer is denser than any gases within the upper chamber volume 120.

When the methyl-containing material is TMA, alumina (AlOₓ) is the metal oxide created, and the by-product gas 328 is methane. In one example, the AlOₓ can be Al₂O₃, Al₂O, AlO₂, or AlO. Alternatively, if the methyl-containing material is TEMAZr, oxidation causes the metal oxide to form as ZrOx, such as ZrO₂, ZrO, in the photoresist layer. When the methyl-containing material is TEMAHf, oxidizing the methyl-containing material produces HfOx, such as is HfO₂, in the photoresist layer. A concentration of the metal oxide is between about 30 percent and about 60 percent of the volume of the photoresist layer. TEMAZr and TEMAHf infiltrate photoresist layer, but do not infiltrate throughout the thickness of the photoresist layer, as compared to TMA. TEMAZr and TEMAHf infiltrate closer to the top surface of the photoresist layer, forming a crust-like layer having TEMAZr and/or TEMAHf along with polymer proximate the top surface, and a layer of polymer proximate the bottom surface. For example, TEMAZr and TEMAHf can infiltrate into the photoresist layer from about 0.05 nm to about 2 nm, such as about 1 nm or about 1.5 nm. As such, polymer is formed throughout the remaining thickness of the photoresist layer. Advantageously, selectivity during subsequent etching of the film stack is higher with ZrOx or HfOx compared to AlOx.

The photoresist layer is exposed to the oxidizing agent at a predetermined pressure, temperature, and time. The oxidizing agent is provided under pressure to the processing volume of the processing chamber, at the high pressure. For example, the oxidizing agent can be provided to the upper chamber volume 120 (i.e., a processing volume) at a pressure between about 100 mTorr to about 10 Torr, such as about 1 Torr to about 10 Torr, or between about 3 Torr and about 7 Torr. A temperature at which the oxidizing agent is provided to the processing volume is between about 50 C and about 100 C, such as between about 75 C and about 100 C.

In one example, the predetermined time at which the oxidizing agent is provided to the upper chamber volume 120 is between about 1 second and about 400 seconds. A hydrolysis reaction oxidizes the methyl-containing material in the photoresist layer for the predetermined time. In another example, the predetermined time is between about 240 seconds and about 350 seconds, such as about 270 second, or about 300 seconds, or about 330 seconds. The predetermined time ensures that the oxidation process occurs between the entirety of the photoresist layer, enabling metal oxide to form uniformly dispersed between the top surface and the bottom surface. If the photoresist layer is exposed to an oxidizing source for less than the predetermined time, a layer of alumina may form near the top surface of the photoresist layer without forming throughout the photoresist layer, thus creating a layer of polymer proximate the bottom surface. If the photoresist layer is exposed to an oxidizing source, such as oxidizing agent, for less than the predetermined time, metal oxide can concentrate at the top surface of the mask creating a crust, despite the methyl-containing material extending through a thickness of the photoresist layer.

The metal oxide formed at operation 208 includes metal atoms and oxygen atoms. In one example, when the methyl-containing material is TMA, the metal atoms are aluminum, thus forming alumina (Al0ₓ) as the metal oxide. Alternatively, when the methyl-containing material is TEMAZr, the metal atoms are zirconium, such that the metal oxide formed is zirconium oxide (Zr0ₓ). In yet another example, when TEMAHf is the methyl-containing material, the metal oxide formed is hafnium oxide (Hf0ₓ), and the metal atoms are hafnium.

At operation 210, the film stack having a treated patterned photoresist layer is etched. For example, the film stack is exposed to etchants, which can be a dry etch or a wet etch. In one example, the film stack is exposed to etchants from a plasma formed from any of the processing gases discussed above, such as a fluorine-containing gas, or a carbon-fluorine containing gas. When exposed to plasma, constituents from the processing gases, including ions, neutrons, protons, and radicals are created when the processing gases are disassociated by the application of an electric field created by the RF generator or DC power source, as detailed above. Advantageously, the metal oxide formed at operation 208 improves etch selectivity at operation 210, as well as the pre-treatment process of operation 202. Optionally, at operation 212, the method 200 may return to operation 202, where another photoresist layer 302 is deposited, and the film stack 300 is again pre-treated and exposed to the methyl-containing material.

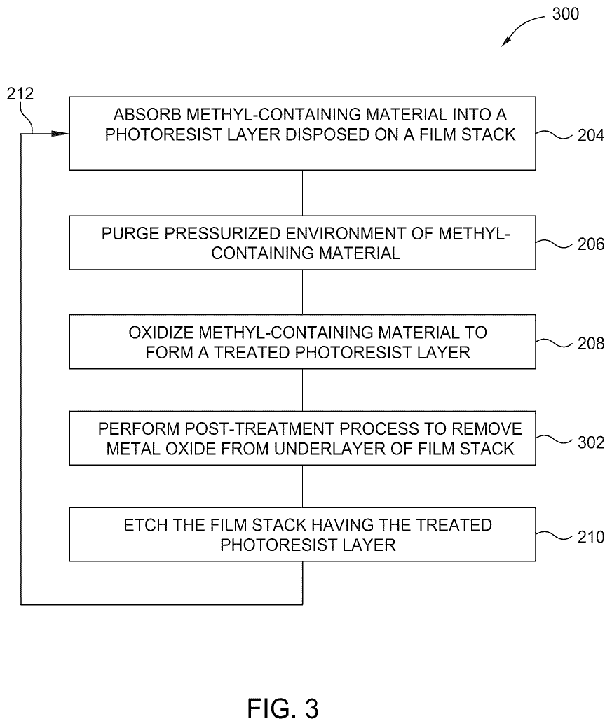

FIG. 3 illustrates a flowchart of a method 300 of patterning a film stack. In one example, the film stack is patterned by a process of photolithography and etching. Similar to the embodiments described with regard to FIG. 2, the film stack includes the substrate 138 having an underlayer disposed on top of and in contact with the substrate. The film stack also includes a photoresist layer disposed on top of and in contact with the underlayer. The photoresist layer includes one or more patterned layers. Exemplary materials for the substrate 138 include silicon, silicon oxide, doped silicon, silicon germanium, germanium, gallium arsenide, glass, sapphire, and any other materials, such as metals, metal nitrides, metal alloys, and other conductive or semi-conductive materials, depending on the application. The substrate 138, or surface thereof, can also be made of dielectric materials such as silicon dioxide, silicon nitride, organosilicates, and carbon dopes silicon oxide or nitride materials.

In one example, the underlayer may be a sol-gel solution or a nanoparticle solution. The first solution may include silicon dioxide (SiO₂) and/or silicon oxycarbide (SiOC). Proportions of SiO₂, SiOC, in the first solution are controlled to result in a first refractive index. For example, the first solution may contain a first ratio of SiO₂, or SiOC. In one embodiment, sol-gel precursors for SiO₂ may include tetramethyl orthosilicate (TMOS), methyl-tri-methoxy-silane (MTMS), and tetraethyl orthosilicate (TEOS). A first refractive layer may include a first material, and a subsequent refractive layer may include a second material different from the first material. A series of refractive layers of metals and/or dielectrics of varying dielectric constants and refractive indices, such as a graded anti-reflective coating (ARC), reduce glare, reflection, or blur. The refractive index of the encapsulation layer can be tuned from over about 2.0 to about 1.47. Exemplary ranges for a refractive index of the underlayer can be between about 1.5 and about 2.0, for example about 1.75. In yet other example, the refractive index of the underlayer 301 can between about 1.0 and about 1.5, for example about 1.47. In yet another example, the refractive index of the underlayer can be between about 1.0 and about 1.5, for example about 1.48 or about 1.49; or between about 1.0 and about 1.5, for example about 1.47.

The method 300 begins at operation 204, proceeds to operation, 206, and then to operation 208, which have been described in detail with regard to FIG. 2. At operation 302, a post-treatment process is performed to remove metal oxide from the underlayer of the film stack which may be formed during the SIS process (operations 204, 206, 208). If metal oxide is present on the underlayer in undesirable regions, e.g. trenches where the metal oxide's presence would lead to a bridge defect, the post-treatment process is performed to remove metal oxide from the underlayer surface.

In one embodiment, the post-treatment process 302 is a chemical etching process operable to selectively remove materials, such as metal oxide materials, from the surface of the underlayer. For example, the post-treatment process 302 is a wet acid etching process. Examples of acids suitable for performing the post-treatment process include, but are not limited to, hydrochloric acid and hydrofluoric acid. Other materials suitable for utilization in the post-treatment process 302 include ferric chloride, sodium hydroxide, potassium hydroxide, or other materials suitable for removing metal oxide materials from the underlayer surface. After performing the post-treatment process 302, the film stack is etched at operation 210.

In certain embodiments, the pre-treatment process 202 is combined with the post-treatment process 302. In this embodiment, the method begins at operation 202 where the pre-treatment process is performed to modify the surface of the underlayer. Then, the SIS process is performed by sequentially performing operations 204, 206, and 208. After performing operation 208, the post-treatment process 302 is performed to remove metal oxide from the surface of the underlayer. Subsequent to the post-treatment process, operation 210 is performed to etch the film stack. While the above referenced embodiments are described with reference to metal oxide containing photoresist materials, the pre-treatment and post treatment processes may be utilized advantageously with non-metal SIS treatment processes. Similarly, the above referenced embodiment have been described with respect to polymer photoresist materials, the embodiments described herein may be advantageously implemented with metal photoresist materials and chemically amplified resist materials.

While the foregoing is directed to examples of the present disclosure, other and further examples of the disclosure may be devised without departing from the basic scope thereof, and the scope thereof is determined by the claims that follow.

What is claimed is:

1. A method for treating a layer of a film stack, comprising:
pre-treating a surface of an underlayer of a film stack formed on a substrate;
forming a metal oxide in a photoresist layer of the film stack by heating a methyl-containing material in a processing environment proximate a film stack, the film stack comprising: the photoresist layer disposed on top of and in contact with an underlayer, and the underlayer disposed on top of a substrate; and
etching the film stack including the photoresist layer implanted with the metal oxide.

2. The method of claim 1, further comprising:
absorbing the methyl-containing material through a top surface of the photoresist layer.

3. The method of claim 2, wherein the methyl-containing material is absorbed throughout a thickness of the photoresist layer, and the metal oxide is alumina.

4. The method of claim 1, further comprising:
maintaining the photoresist layer at a pressure to enable the methyl-containing material to absorb throughout a thickness of the photoresist layer.

5. The method of claim 1, wherein the pre-treating the surface of the underlayer comprises forming a SAM material on the surface of the underlayer

6. The method of claim 5, wherein the SAM material is formed by exposing the surface of the underlayer to hexamethyldisilazane.

7. The method of claim 1, further comprising:
oxidizing the methyl-containing material in the photoresist layer.

8. The method of claim 1, further comprising:
purging the processing environment of the methyl-containing material, prior to oxidizing the methyl-containing material.

9. The method of claim 1, further comprising:
oxidizing the methyl-containing material in the photoresist layer; and
converting substantially all of the methyl-containing material to alumina.

10. The method of claim 9, wherein the film stack is etched with a fluorine-containing gas, or a carbon-fluorine containing gas.

11. A method for treating a layer of a film stack, comprising:
forming a metal oxide in a photoresist layer of the film stack by heating a methyl-containing material in a processing environment proximate a film stack, the film stack comprising: the photoresist layer disposed on top of and in contact with an underlayer, and the underlayer disposed on top of a substrate;
performing a post-treatment process on a surface of the underlayer to remove the metal oxide from the underlayer; and
etching the film stack and the photoresist layer comprising the metal oxide.

12. The method of claim 11, wherein the post-treatment process comprises a wet etch process.

13. The method of claim 12, wherein the wet etch process comprises exposing the surface of the underlayer to hydrochloric acid or hydrofluoric acid.

14. The method of claim 11, further comprising:
oxidizing the methyl-containing material in the photoresist layer.

15. The method of claim 11, further comprising:
purging the processing environment of the methyl-containing material, prior to oxidizing the methyl-containing material.

16. The method of claim 15, further comprising:
oxidizing the methyl-containing material in the photoresist layer for a predetermined time between about 1 second and about 400 seconds.

17. The method of claim 11, further comprising:
oxidizing the methyl-containing material in the photoresist layer; and
converting substantially all of the methyl-containing material to alumina, wherein the film stack is etched with a fluorine-containing gas, or a carbon-fluorine containing gas.

18. A substrate processing method, comprising:
disposing a substrate comprising an underlayer and a photoresist layer in a process chamber;
performing a pre-treatment process on a surface of the underlayer to form a SAM material on the surface of the underlayer;
exposing the photoresist layer to a methyl-containing material;
purging the process chamber of the methyl-containing material;
oxidizing the methyl-containing material to form a treated photoresist;
performing a post-treatment process on the surface of the underlayer to remove a metal oxide material from the surface of the underlayer; and
etching the photoresist layer and the underlayer.

19. The method of claim 18, wherein the surface of the underlayer after the pre-treatment process is hydrophobic.

20. The method of claim 19, wherein the surface of the underlayer after the post-treatment process is substantially free of the metal oxide material.
